(19) United States
(12) Patent Application Publication
(10) Pub. No.: US 2023/0380165 A1
(43) Pub. Date: Nov. 23, 2023

(54) MEMORY DEVICE WITH HIGH-MOBILITY OXIDE SEMICONDUCTOR CHANNEL AND METHODS FOR FORMING THE SAME

(71) Applicant: Applied Materials, Inc., Santa Clara, CA (US)

(72) Inventor: Milan PESIC, Paoli, PA (US)

(21) Appl. No.: 18/198,043

(22) Filed: May 16, 2023

Related U.S. Application Data
(60) Provisional application No. 63/343,086, filed on May 17, 2022.

(51) Int. Cl. H10B 43/27; H10B 41/27

(52) U.S. Cl. CPC H10B 43/27; H10B 41/27

(57) ABSTRACT

Embodiments of the disclosure include an apparatus and method of forming a memory device with high-mobility oxide semiconductor channels. In some embodiments, the apparatus, for example, includes a plurality of alternating layers formed over a surface of a substrate; a gate coupled to each of the word line layers of the plurality of alternating layers; a multi-layer channel memory cell having a first end coupled to a source region, a second end coupled to a drain region, and extending in the first direction between the source region and the drain region, the multi-layer channel also having a first conductive layer and a second conductive layer, the first conductive layer being different from the second conductive layer; and an ONO layer stack disposed between the gates and the multi-layer channel, wherein the ONO layer stack extends in the first direction between the source region and the drain region.

### CROSS-REFERENCE TO RELATED APPLICATION(S)

This application claims the benefit of and priority to U.S. Provisional Application 63/343,086 filed on May 17, 2022, which is herein incorporated by reference.

### BACKGROUND

### Field

The present disclosure generally relate to memory devices, and methods of manufacturing the same, and more particularly, to device structures and methods of forming three-dimensional (3D) memory devices.

### Description of the Related Art

Memory devices are an essential component in digital electronic devices that are being developed today. With the increase in technology today, there is a need for increased memory capacity in most electronic devices. At the same time there is also a need for smaller memory devices to meet the market place's desire to create smaller electronic devices in which the memory device is positioned within.

In recent years, conventional (2D) NAND memory devices have run into a number of challenges, including voltage drop related issues (e.g., running out of electrons in the current carrying elements due to the ever scaling of the cell size), retention loss and overall reliability. To address challenges encountered in scaling planar 2D NAND memory devices to achieve higher densities at a lower cost per bit, ultra-high density, three-dimensional (3D) stacked memory structures have been introduced. Such 3D memory structures are sometimes referred to as having a Bit Cost Scalable (BiCS) architecture, and include strings of vertically integrated memory cells. Typically, the vertically aligned memory cells are formed from an array of alternating conductor and insulator layers, where the conductive layers correspond to the word lines of the memory structure.

As the number of vertically stacked memory cells in 3D NAND devices increases (e.g., as chip densities increase), the resistivity of the memory cell string (e.g., channel structure) also increases, introducing numerous performance issues. As resistivity increases, more advanced circuits are required for current sensing. Typically, the memory cell string may include a number of word line layers. As the number of vertically stacked layers increase, the overall resistance of the vertically oriented channel region of the 3D NAND memory increases, leading to a drop in the amount of current that can (1) flow in the channel structure and most importantly (2) be detected at by the sense amplifier. Based on the current design rules and pitches, at around 500 stacked word line layers, it may not be possible to detect any current flowing through the channel region which corresponds to the stored state. In turn, the difference between stored states is indistinguishable. Currently, it is common to utilize a polysilicon channel in the channel structure of a 3D NAND device. As a result of the use of a polysilicon channel and its highly granular nature, the 3D NAND device may be suffer from reduced mobility, ON current degradation, increased device variability, as well as retention degradation. In past a macaroni type 3D NAND device were suggested and implemented that comprise off the filler oxide which minimizes the thickness of the polysilicon channel and in turn reduce the number of grain boundaries (GBs) responsible for the electron scattering and improve the ON current. Even though the number of GBs is reduced in this approach, they are still present and cannot overcome the 500 WL stacking limit.

Therefore, there is a need for an improved memory device structure and method of forming the same that solves the problems described above.

### SUMMARY

Embodiments of the disclosure may provide a three-dimensional memory device, comprising a plurality of alternating layers formed over a surface of a substrate, wherein the alternating layers comprises a word line layer and an inter-word line dielectric layer that are stacked in a first direction and a gate coupled to each of the word line layers of the plurality of alternating layers. The three-dimensional memory device also includes a multi-layer channel having a first end coupled to a source region, a second end coupled to a drain region, and extending in the first direction between the source region and the drain region. The multi-layer channel comprises a first conductive layer extending between the source region and the drain region; and a second conductive layer extending between the source region and the drain region, wherein the first conductive layer is different from the second conductive layer. The three-dimensional memory device also includes an ONO layer stack disposed between the gates and the multi-layer channel, wherein the ONO layer stack extends in the first direction between the source region and the drain region.

Embodiments of the disclosure may provide a three-dimensional memory device, comprising a plurality of alternating layers formed over a surface of a substrate, wherein the alternating layers comprises a word line layer and an inter-word line dielectric layer that are stacked in a first direction and a gate coupled to each of the word line layers of the plurality of alternating layers. The three-dimensional memory device also includes a multi-layer channel having a first end coupled to a source region, a second end coupled to a drain region, and extending in the first direction between the source region and the drain region. The multi-layer channel comprises a first conductive layer extending between the source region and the drain region; and a second conductive layer extending between the source region and the drain region, wherein the first conductive layer is different from the second conductive layer. The multi-layer channel also includes a filler layer extending between the source region and the drain region. The three-dimensional memory device also includes an ONO layer stack disposed between the gates and the multi-layer channel, wherein the ONO layer stack extends in the first direction between the source region and the drain region.

Embodiments of the disclosure can provide a method of forming a three-dimensional memory device, comprising forming a plurality of alternating layers over a surface of a substrate. The method of forming a plurality of alternating layers comprises a dielectric layer (later in process etched and replaced with word line layer) and an inter-word line dielectric layer that are stacked in a first direction over a source region layer that is disposed over the surface of the substrate, wherein each word line layer is coupled to one or more gates. The method of forming a plurality of alternating layers also comprises a plurality of openings (memory holes) extending in the first direction from the source region layer and through the plurality of alternating layers, wherein a portion of a gate of the one or more gates in each word line layer are positioned adjacent to a surface of each opening of the plurality of openings. The method of forming a three-dimensional memory device also comprises forming a memory cell/stack regions and channel region within the plurality of openings. The method of forming the cell region comprises forming an ONO layer stack over the surface of each of the plurality of openings; forming a first conductive layer (channel #1) over a surface of the ONO layer stack; and forming a second conductive layer (channel #2) over a surface of the first conductive layer, wherein the first conductive layer is different from the second conductive layer. The method of forming a three-dimensional memory device also comprises forming a drain region layer over the plurality of alternating layers, wherein at least a portion of the first conductive layer and a portion of the second conductive layer formed within each of the plurality of openings are coupled to a portion of the drain region layer and at least a portion of the first conductive layer and a portion of the second conductive layer are coupled to a portion of the source region layer.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a simplified schematic example of a three-dimensional memory structure 100.

FIG. 2 illustrates a schematic side cross-sectional view of a portion 200 of the 3D NAND memory structure 100, according to one or more of the embodiments described herein.

FIG. 3 illustrates a schematic side cross-sectional view of an alternate configuration of the 3D NAND memory structure 100, which illustrates a portion 300 of the 3D NAND memory structure 100, according to one or more of the embodiments described herein.

FIG. 4 is an energy band diagram illustrating an example of multi-channel energetic configuration, according to one or more of the embodiments described herein.

FIG. 5A is a schematic view of a portion of a conventional 3D NAND memory cell.

FIG. 5B is a schematic view of a portion of a memory cell of the 3D NAND memory structure and a related charge density diagram for the multiple channels with the 3D NAND memory structure, according to one or more of the embodiments described herein.

FIG. 6 illustrates a method 600 for use in the manufacturing of memory cell gate stack portion of a semiconductor device, such as forming a portion 200 or a portion 300 of the 3D NAND memory structure 100, according to one or more of the embodiments described herein.

FIG. 7, illustrates a schematic side cross-sectional view of a portion 700 of the 3D NAND memory structure 100 during formation, according to one or more of the embodiments described herein.

FIG. 8 illustrates a schematic side cross-sectional view of a portion 800 of a 3D NAND memory structure 100 during formation, according to one or more of the embodiments described herein.

FIG. 9 illustrates a schematic side cross-sectional view of a portion 900 of a 3D NAND memory structure 100 during formation, according to one or more of the embodiments described herein.

FIG. 10 illustrates a schematic side cross-sectional view of a portion 1000 of a 3D NAND memory structure 100 during formation, according to one or more of the embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

Embodiments of the disclosure provided herein include an apparatus for and method of forming an improved three-dimension (3D) memory structure/cell that includes a multi-layer channel that includes two or more layers that are formed of different materials. In some embodiments, the material of each channel layer may be an amorphous oxide semiconductor material. The formed multi-layer channel described herein can allow for multiple pathways for a current transport and may conduct a higher total current, through the two or more layers of the multi-layer channel during operation. In one embodiment, the two or more layers include a low mobility channel layer and a high mobility channel layer, which are used to increase the speed and reliability of the 3D NAND device due to a higher magnitude of the current that can be conducted through the channel region of the device. The multi-layer channel may include a plurality of layers with differing electron mobilities. For example, the multi-layer channel may include three layers. In this example, the outer layers may act as protection layers for the inner layer. The combination of a low mobility layer and a high mobility layer may result in improved performance for the 3D memory structure, as described herein. For example, the multi-layer channel structure may allow for the utilization of amorphous channel materials, which can decrease and/or eliminate electron scattering created at the grain boundaries of conventional polycrystalline silicon containing channel regions. As a consequence of the decrease in electron scattering at the grain boundaries (amorphous semiconducting oxides are grain-boundary free), the channel structure and whole memory string exhibit a decreased resistance and variability. Additionally, as described above, the mobility of the channel structure and the ON current of the device may also both be improved due to the lack of grain boundaries found in the amorphous structure. As a result, the multi-layer channel in the channel structure may enable a greater number of word lines (e.g., more than 500 word lines) in the 3D memory structure. Transitioning to amorphous multi-channel oxide semiconductor channels and inherent absence of the grain boundaries (typically present in prior-art polysilicon channels) results in reduction of the scattering mechanisms (largest contributor to the variability of the stored bit) which will also allow for an increase in the number of states that can be stored in a multi-level cell, (e.g., more efficient and dense storage density).

Beside the application in the memory devices, this approach can be applied in logic as well to improve the so-called fan-out. The fan-out is the number of gate inputs driven by the output of another single logic gate. Furthermore, as a result of the multi-layer channel in the transistor structure, fan-out may be increased, due to the improved conductivity of the channel structure.

Embodiments disclosed herein can be useful for, but are not limited to, channel structures in two dimensional (2D) and 3D memory including a multi-channel layer with layers having differing mobilities.

### High-Mobility Oxide Semiconductor Channel

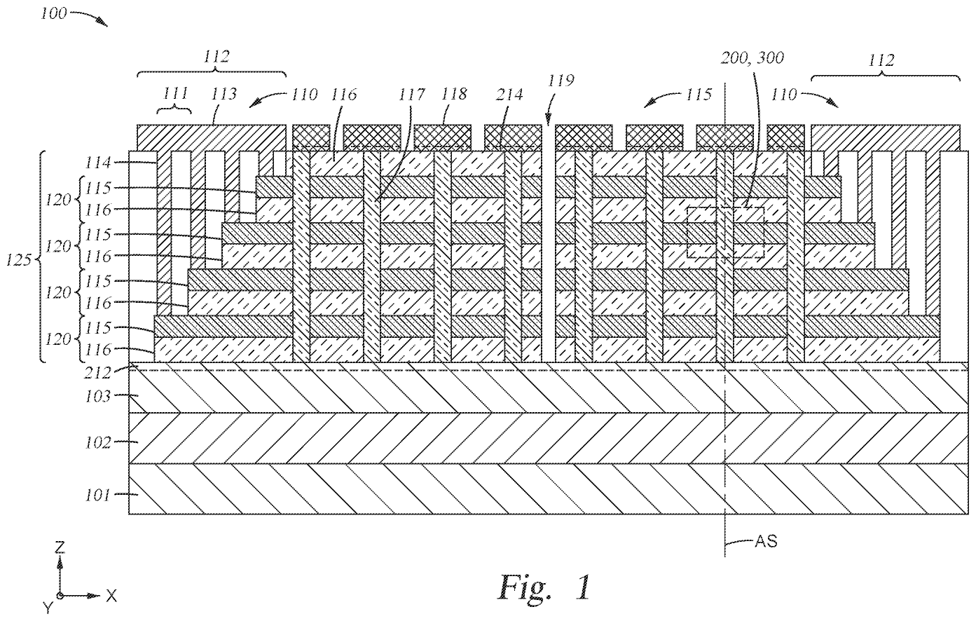

FIG. 1 is a simplified schematic example of a 3D NAND memory structure 100. The 3D NAND memory structure includes a channel structure 117 that is oriented in a vertical direction, such that the channel structure 117 is oriented perpendicular (e.g., −Z-direction) to a major surface of the substrate 101 that includes an etch stop layer (ESL) 102 and a common source line layer (CSL) 103 disposed thereon. The top of the vertical channel layer structure 117 includes a plurality of bit lines 118. The stacked layers are configured in stacked layer pairs 120 that each include a dielectric layer 116 and a word line layer 115. In this configuration, the word line layers 115 (e.g., four layers shown in FIG. 1) are stacked in the direction that is perpendicular to the major surface of the substrate to form a string of memory cells and each include a portion of one of the channel layer structures 117. At an end of each word line layer 115 is a staircase-like structure 110. In the staircase-like structure 110 and one or more conductive columns 114 are used to connect the word line layer 115 to an external control circuit by use of connecting element lines 113. In this way, in the 3D NAND memory structure, a memory cell may be fabricated in a vertical direction, so that a memory capacity may be easily increased by stacking additional layers. A gate slit line 119 may also be formed through the 3D NAND memory structure 100. It should be noted that the word line layer 115 is deposited later in the process of forming the NAND device by removing the dummy (second) dielectric material by use of an etching process and then depositing a conductive layer in same place where the dummy (second) dielectric was positioned.

The 3D NAND memory structure 100 may also include a source region 212 (e.g., N+ source layer), which may be part of or formed on the CSL 103, and a drain region 214 (e.g., N+ drain layer), which may be part of or formed under the plurality of bit lines 118. The staircase-like structures 110, which are formed on two opposing edges of the 3D NAND memory structure 100, require a two-dimensional area (i.e., X-Z plane) to connect all of the word line layers 115 to external elements outside of the 3D NAND device.

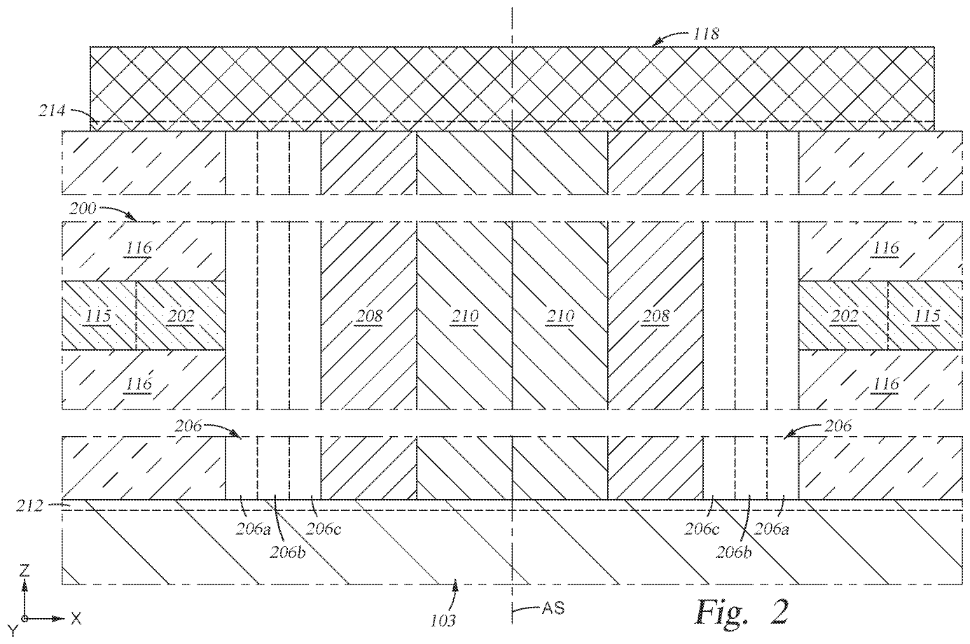

FIG. 2 illustrates a schematic side cross-sectional view of a portion 200 of the 3D NAND memory structure 100, according to one or more of the embodiments described herein. The portion 200 of the 3D NAND memory structure 100 is taken from the portion illustrated within the labelled dashed box found in FIG. 1. The portion 200 of the 3D NAND memory structure 100 is a close-up or detailed view of a portion of a memory cell that includes a portion of a channel structure 117 and portions of adjacent stacked layer pairs 120, which includes portions of dielectric layers 116 (e.g., inter-word line dielectric layer), a portion of a word line layer 115, and a gate region 202. The channel structure 117 includes a first channel 208 and a second channel 210 that form a multi-layer channel. The first channel 208 may include a first conductive layer, and the second channel 210 may include a second conductive layer. While not intending to limit the scope of the disclosure provided herein, the first channel 208 will include a conductive material that has a different composition than the material used to form the second channel 210. In some configurations, the gate stack of a memory device can also include a filler oxide in the center of the axis of symmetry or differently etched and organized storage (ONO charge trapping) layer (e.g. forming a partial or full charge trap layer).

In some embodiments, the first channel 208 material may include indium zinc oxide (IZO), the second channel 210 material may include indium gallium zinc oxide (IGZO), and the second channel 210 may be disposed over the first channel 208. The first channel layer 208 and second channel layer 210 may include any material that allows for the flow of electrons between a source region 212 and a drain region 214, as is provided in more detail below. In some embodiments, the first channel layer 208 may have different electron mobility than the electron mobility of the second channel layer 210. In one example, the first channel layer 208 may be a high electron mobility layer, and the second channel layer 210 may be a lower electron mobility layer. In some embodiments, the first channel layer 208 and the second channel layer 210 may both include a low mobility layer or both include a high mobility layer. In some embodiments, the combination of the first channel layer 208 and the second channel layer 210 results in the multi-layer channel having an effective mobility of from about 1 cm²N s to about 70 cm²N s, such as about 25 cm²N s to about 60 cm²N s, such as about 25 cm²N s to about 35 cm²N s, or from about 35 cm²N s to about 60 cm²N s.

In embodiments where the first channel 208 has a mobility greater than the mobility of the second channel 210, the first channel 208 conducts a large portion of the current through the multi-layer channel, which allows the multi-layer channel to effectively conduct current due to the high mobility of the first channel 208. The combination of the first channel 208 and the second channel 210 results in the multi-layer channel having an effective mobility greater than about 60 cm²N·s. The first channel 208 has a mobility less than about 20 cm²N·s, and the second channel 210 has a mobility greater than about 60 cm²N·s, according to one embodiment.

As discussed above, the 3D NAND memory structure 100 includes a dielectric layer 116 (e.g., inter-word line dielectric layer), a word line layer 115, and a gate region 202, as shown in FIG. 2. In some embodiments, the gate region 202 may be the same material as the word line layer 115. In other embodiments, the gate region 202 may be a different material (or different combination of the materials) than the word line layer 115 to adjust the work function of the gate region in the memory cell device. The dielectric layer 116, word line layer 115, and gate region 202 may extend from a position adjacent to the channel structures 117 of the 3D NAND memory structure 100 to a conductive column 114 in a direction that is parallel (e.g., −X-direction) to a major surface of the substrate 101.

The 3D NAND memory structure 100 includes a charge trapping layer structure 206 disposed between the gate regions 202 and the multi-layer channel (e.g., first channel 208 and second channel 210). While not intending to limit the scope of disclosure provided herein the charge trapping layer structure is also referred to herein as an ONO layer stack 206. The ONO layer stack 206 will include a first dielectric layer 206a, a charge trap layer 206b, and a second dielectric layer 206c. In one example, the first dielectric layer 206a includes a silicon oxide material (e.g., SiO₂ layer), the charge trap layer 206b includes a silicon nitride (SiN) layer, and the second dielectric layer 206c includes a silicon oxide or an aluminum oxide containing layer.

In some embodiments, the abbreviated ONO stack can be a combination of various thicknesses of materials which form the tunnel oxide, charge-trapping (storage) layer, blocking oxide and/or high-k layer. A tunnel oxide can be formed by a combination of various thicknesses of SiO₂/SiN/SiO₂, and in some cases the SiN layer includes a completely different stoichiometry and properties compared to the charge-trapping SiN layer. In some embodiments, the tunnel oxide is formed from of a silicon oxide (SiOₓ), whereas an aluminum oxide (AlₓO_{y}) is the most commonly used high-k layer. Other tunnel oxide materials can include, but are not limited to, a hafnium oxide material (HfOₓ), or a doped hafnium oxide material that contains one or more of Al, Y, Si, N, Sr, or Gd as a dopant. In some cases, the ONO layer stack 206 is referred to herein as an “intermediate layer stack”. In some embodiments, the intermediate layer stack includes the first dielectric layer 206a, the charge trap layer 206b, and the second dielectric layer 206c. However, in some alternate embodiments, the intermediate layer stack includes a ferroelectric material containing layer. In one example, the intermediate layer stack includes HfOₓ, or a HfOₓ material that is doped with Si, Al, Y, N, Zr, or Sr. In another example, the intermediate layer stack includes a scandium (Sc) containing material, or scandium material doped aluminum nitride (AlNₓ).

The 3D NAND memory structure 100 may also include a source region 212, which may be part of a CSL (e.g., 103) and a drain region 214 which may be part of a plurality of bit lines 118. The first channel 208 extends between the source region 212 and the drain region 214 perpendicular (e.g., −Z-direction) to a major surface of the substrate 101. The second channel 210 also extends between the source region 212 and the drain region 214 perpendicular (e.g., −Z-direction) to a major surface of the substrate 101. The ONO layer stack will also extend between the source region and the drain region perpendicular (e.g., −Z-direction) to a major surface of the substrate 101.

The channel structures 117 and ONO layer stack 206 of the 3D NAND memory structure 100 may be symmetrical across the axis of symmetry (AS), as depicted in FIG. 2. For example, the memory structure may include another second channel 210, first channel 208, ONO layer stack 206, a dielectric layer 116 (e.g., inter-word line dielectric layer), a word line layer 115, and gate region 202 across or on opposing sides of the axis of symmetry.

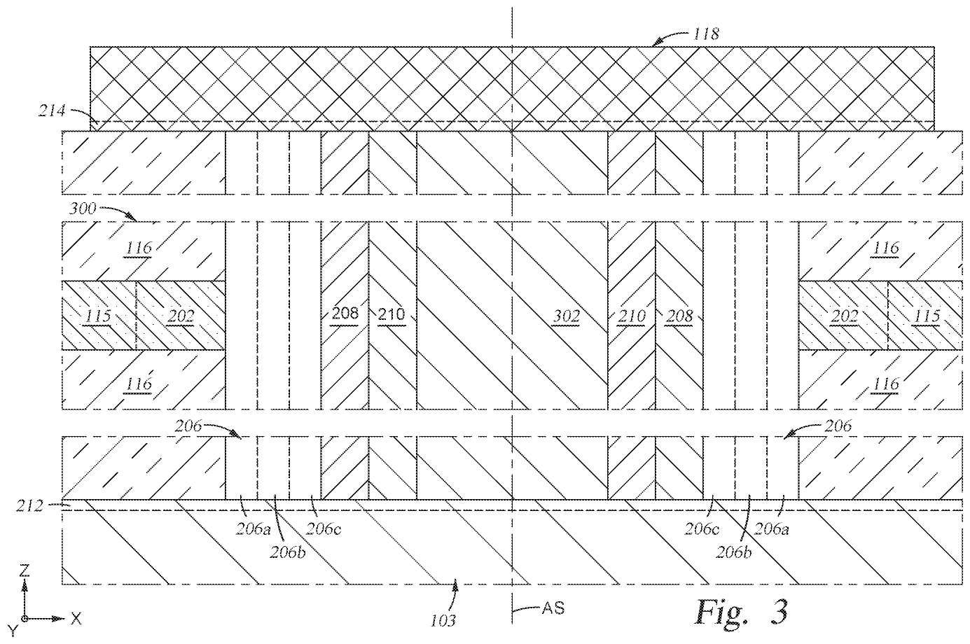

FIG. 3 illustrates a schematic side cross-sectional view of an alternate configuration of the 3D NAND memory structure 100, which illustrates a portion 300 of the 3D NAND memory structure 100, according to one or more of the embodiments described herein. The portion 300 of the 3D NAND memory structure 100 is taken from the portion illustrated within the labelled dashed box found in FIG. 1. The portion 300 of the 3D NAND memory structure 100 is a close-up or detailed view of a portion of a memory cell that includes a portion of a channel structure 117 and portions of adjacent stacked layer pairs 120, which includes portions of dielectric layers 116 (e.g., inter-word line dielectric layer), a portion of a word line layer 115, and a gate region 202. The portion 300 may be similar to the portion 200 in FIG. 2 described herein, and includes a first channel 208, second channel 210, ONO layer 206, a dielectric layer 116 (e.g., inter-word line dielectric layer), a word line layer 115, and gate region 202, as described above.

The portion 300 also includes a dielectric filler layer 302 that is disposed within the channel structure 117. The filler layer 302 can be used to balance the cross-sectional area ratio (X-Y plane) between the first channel 208 and the second channel 210 and in this way to adjust the voltage/capacitance divider which may be used as a design rule. The filler layer 302 material may include silicon dioxide (SiO₂), aluminum oxide (Al₂O₃), silicon nitride (SiN), silicon oxycarbide (SiOₓC_{y}), or another suitable material. The portion 300 may be symmetrical across the axis of symmetry (AS), as depicted in FIG. 3.

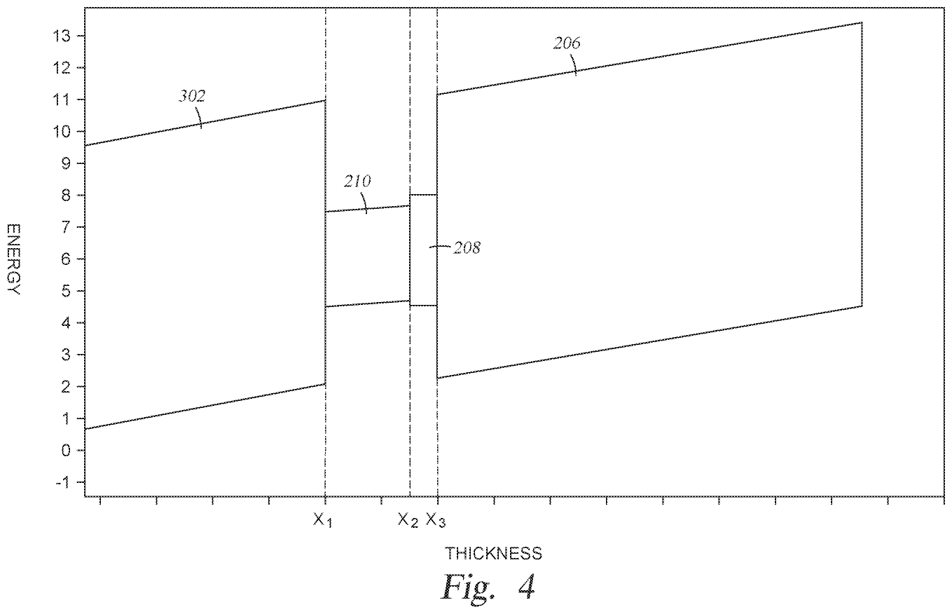

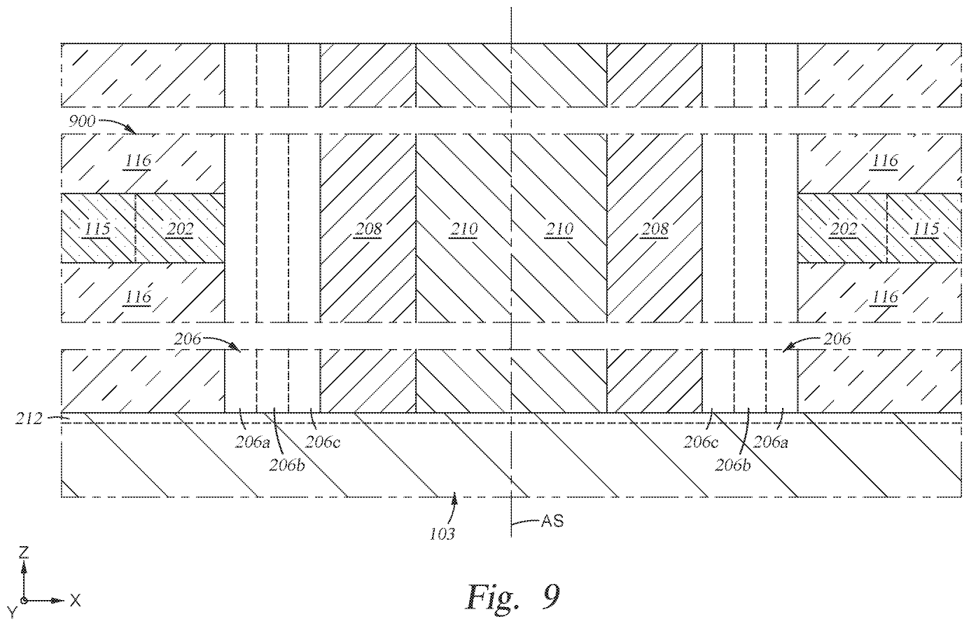

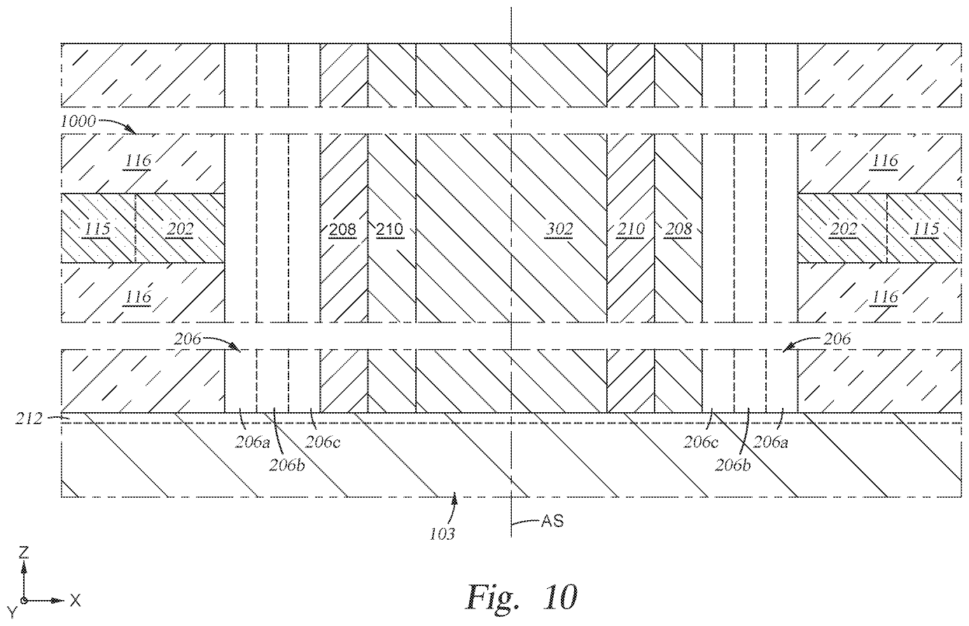

FIG. 4 is an energy band diagram illustrating an example of multi-channel structure, according to one or more of the embodiments described herein. In this example, as shown in FIG. 4, the band structure of a memory cell within the 3D NAND memory structure 100 includes the band structures of the substrate, multi-layer channel and ONO stack 206. The multi-layer channel includes an IZO layer (e.g., first channel 208) that extends between X₁ and X₂, and an IGZO layer (e.g., second channel 210) that extends between X₂ and X₃ and forms a hetero structure that is disposed between the filler oxide 302 (left band structure) and ONO stack 206 band structure (right band structure). Due to simplicity and multiple band-gap engineered combinations of ONO stack, here ONO stack is represented simplified as a single bandgap material. The IZO layer and the IGZO layer may have different band gaps, as illustrated in FIG. 4. For example, by applying a voltage to the gate insulator (e.g., ONO stack 206), both the IZO layer and the IGZO layer may be opened up in the memory device and thus allow conduction of electrons therethrough. The IZO layer may act as a positive feedback and may feed (inject) electrons into the IGZO layer. Moreover, absolute thicknesses of channels and ratio between them (provided in figure) is just illustrative purposes and should not only cover the situation where inner channel is having larger thickness compared to the outer channel (when observed from the center of axis of symmetry). In some embodiments, the channel in contact with second dielectric layer 206c (e.g., one of the first channel 208 or the second channel 210) may act as a protection layer, protecting the center channel layer (e.g., the other of first channel 208 or the second channel 210) from scavenging, oxygen (O) depletion, and unintentional parasitic doping by hydrogen (H) and similar process gasses. For example, first channel 208 may serve as a protection layer for the second channel 210, as illustrated in FIG. 9. In another example, first channel 208 and filler layer 302 may serve as protection layers for second channel 210, as illustrated in FIG. 10.

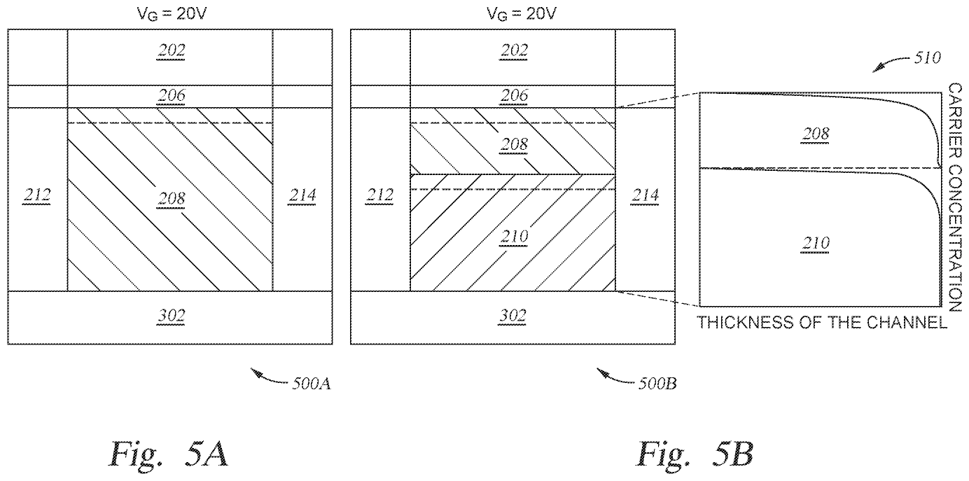

FIGS. 5A, and 5B are schematic views of a portion of a conventional 3D NAND memory cell and a memory cell of the 3D NAND memory structure 100 described herein, respectively. FIGS. 5A and 5B are provided to illustrate some of the differences between a conventional single layer channel (e.g., polysilicon containing channel) and a multi-layer channel operation, according to one or more of the embodiments described herein. FIG. 5A illustrates current flow though a single channel structure in a conventional 3D NAND memory device. In FIG. 5A, the 3D memory device includes a single layer channel 208 that is disposed between a filler oxide 302 on one side and ONO layers 206 and a gate region 202 on the other side. During operation, when applying a voltage between the source region 212 (e.g., N+ source layer) and drain region 214 (e.g., N+ drain layer) and applying a gate voltage in the gate region 202 may cause electrons to flow in the single channel 208. The electrons may be attracted to the gate region 202 bias and may primarily flow in the top region of the single channel 208 nearest to the gate region 204. The top region of the single channel 208 has a small area, and may only enable a small amount of current to flow.

FIG. 5B includes a depiction of the memory cell of the 3D NAND memory structure 100 and graph 510, which illustrates an example of a measure of the charge density in the memory cell of the 3D NAND memory structure 100 during operation. Graph 510 is intended to illustrate the double carrier concentration and double inversion regions formed inside a multi-channel structure in the 3D NAND memory structure 100. During operation, the two inversion regions conduct the current between the source and drain layers while the amount of the inversion and magnitude of the current flowing is tuned or controlled by the voltage applied to the control gate region. In FIG. 5B, the 3D memory device has a first channel 208 and a second channel 210 between a filler oxide 302 on one side and ONO layers 206 and a gate region 202. During operation, when applying a voltage between the source region 212 (e.g., N+ source layer) and drain region 214 (e.g., N+ drain layer) and applying a gate voltage in the gate region 202 may cause electrons to flow in the single channel 208 and also within the second channel region 210. The magnitude of inversion and current flow through these regions will be controlled by the gate region 202. The top region of the single channel 208 and the top region of the second channel 210 combine to form a larger area to conduct a current when a bias is applied between the source and drain regions, as compared to the single layer channel operation in FIG. 5A. In addition to the two parallel channels that conduct the current between the source and drain, a carrier injection is believed to take place from one to the other channel in turn increasing the magnitude of the current. The multi-layer structure thus creates lower resistance pathways through which the current can flow, and thus enables a larger amount of current to flow within the channel structure 117. The graph 510, shown on the right hand side of FIG. 5B, illustrates an example of a carrier concentration along the channel thickness for the materials found in the first channel 208 and second channel 210 positioned adjacent to a gate region 202 during the operation of a memory cell. The portion of the memory cell illustrated on the left hand side of FIG. 5B, for which the band structure is graph is representative of, includes a portion of the multi-layer channel region.

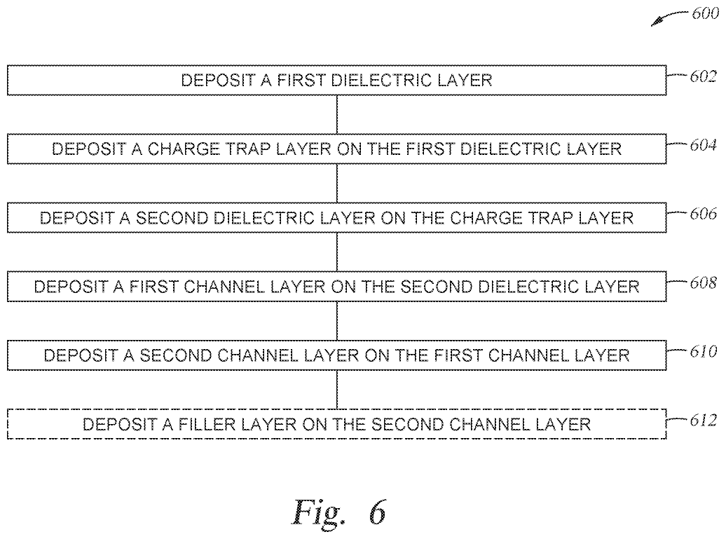

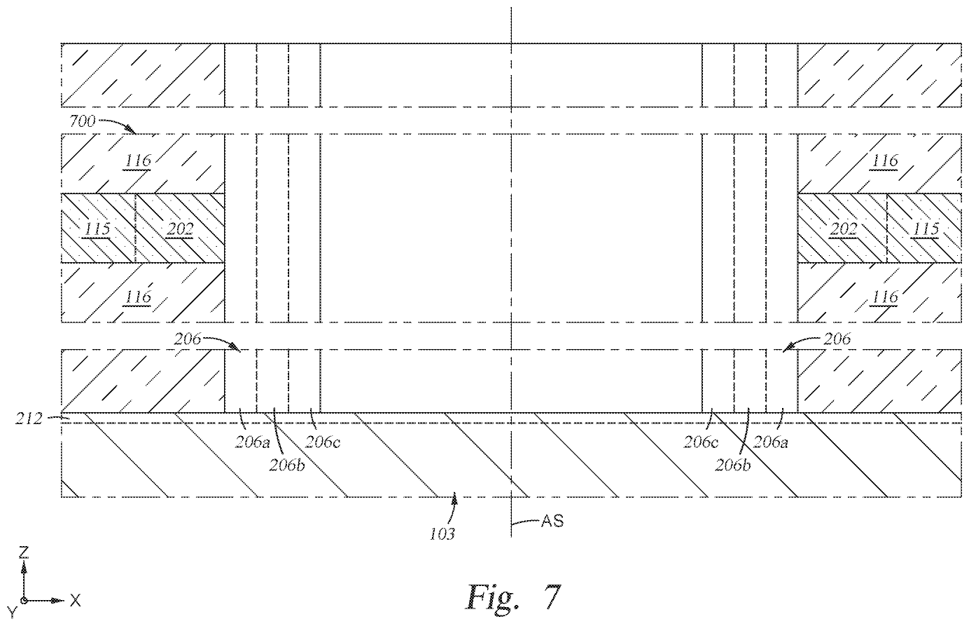

FIG. 6 illustrates a method 600 for use in the manufacturing of cell portion of a semiconductor device, such as forming a portion 300 of the 3D NAND memory structure 100, according to one or more of the embodiments described herein.at least part of the 3D NAND memory structure 100. FIGS. 7, 8, 9, and 10 illustrate schematic side cross-sectional views of portions 700, 800, 900, 1000 of the 3D NAND memory structure 100 during one or more of the activities illustrated in FIG. 6, according to one or more of the embodiments described herein. In other words, it is assumed that the mold is previously deposited and that memory holes are opened by high aspect ratio etching.

The method 600 assumes that a memory gate stack and channel structure 117 is ready to be formed in a 3D NAND memory structure 100. The preparation for the formation of a channel structure 117 may include forming a plurality of openings (e.g., memory holes) that extend from a CSL 103 through a plurality of alternating layers 125 perpendicular (e.g., −Z-direction) to a major surface of the substrate 101.

At activity 602 a first dielectric layer 206a (FIG. 7) is deposited on the side walls of a plurality of openings in a portion 700 of the 3D NAND memory structure 100 by use of an atomic layer deposition (ALD) or chemical vapor deposition (CVD) process. The process of depositing the first dielectric layer may include, for example, depositing a layer (e.g., a continuous layer) of aluminum oxide (Al₂O₃ or similar) and or silicon oxide (SiOₓ) on sides that define the plurality of openings formed in the plurality of alternating layers 125 and along the CSL 103 and/or ESL 102 at the bottom of the plurality of openings. The first dielectric layer(s) are forming so-called barrier oxide and high-k layer of the memory cell.

At activity 604, a charge trap layer 206b (FIG. 7) is deposited in the plurality of openings in a portion 700 of the 3D NAND memory structure 100 on the first dielectric layer 206a by use of an atomic layer deposition (ALD) or chemical vapor deposition (CVD) process. The charge trap layer 206b may include a layer of trap-silicon nitride (Si₃N₄), or even a polycrystalline silicon (poly-Si) layer (floating gate NAND cell architecture).

At activity 606, a second dielectric layer 206c (FIG. 7) is deposited in the plurality of openings in a portion 700 of the 3D NAND memory structure 100 on the charge trap layer 206b by use of an atomic layer deposition (ALD) or chemical vapor deposition (CVD) process. The second dielectric layer 206c may include a layer of silicon oxide (SiOₓ) or band-gap engineered combination of the SiO₂/SiN/SiO₂. The second dielectric layer 206c, or the combination of band-gap engineered layers, can be used to form a tunneling oxide region of the device. The first dielectric layer 206a, the charge trap layer 206b, and the second dielectric layer 206c altogether form the simplified ONO dielectric layer stack 206.

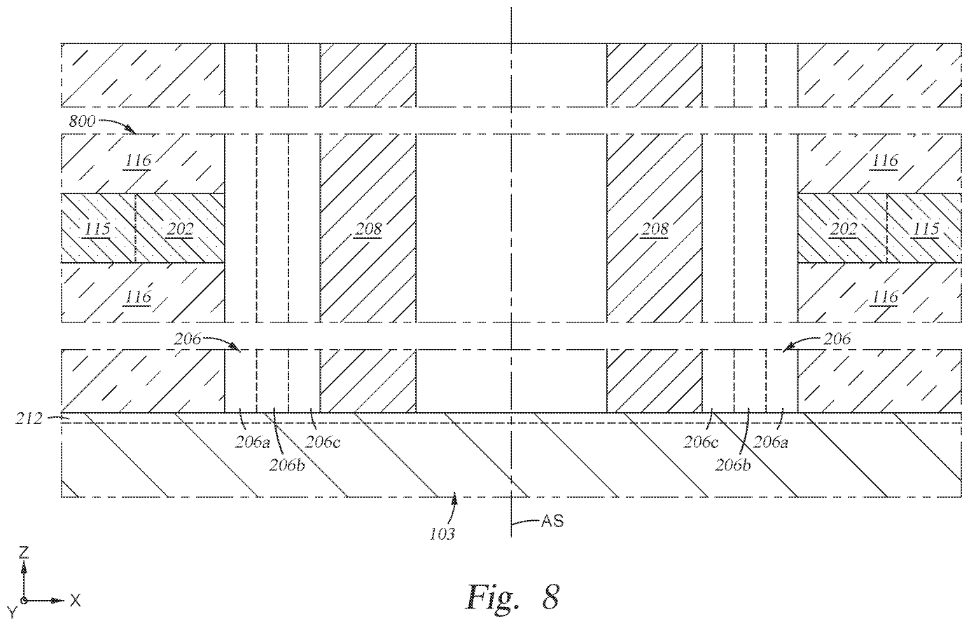

At activity 608, as shown in FIG. 8, a first channel layer 208 is deposited in the plurality of openings, as illustrated in a portion 800 of the 3D NAND memory structure 100, and on the second dielectric layer 206c by use of an atomic layer deposition (ALD) or chemical vapor deposition (CVD) process. For example, the first channel layer (e.g., 208) may be an amorphous indium zinc oxide (IZO) containing layer, as described herein with respect to FIGS. 2 and 3.

In some embodiments, the method 600 may optionally include an etching process to remove portions of the deposited dielectric layers in the ONO layer stack 206, such as layers 206a, 206b, 206c, after performing activities 602-604 in order to remove the portions of the layers 206a, 206b, 206c from the bottom of the plurality of openings and allow the subsequently deposited first channel 208 to contact the source region 212 (N+ source layer) after performing activity 608. The etching of the bottom portion of the layers 206a, 206b, 206c will be performed before the deposition of the first channel layer 208 in activity 608, and may involve a sputter etching process, a wet etch, and/or a chemical dry etch.

At activity 610, a second channel layer 210 (FIG. 9) may be deposited in the plurality of openings in a portion 900 of the 3D NAND memory structure 100 on the first channel layer 208 by use of an atomic layer deposition (ALD) or chemical vapor deposition (CVD) process. For example, the first channel layer may be indium zinc oxide (IZO), and the second channel layer material may be an amorphous indium gallium zinc oxide (IGZO) containing layer. In some embodiments, the deposition of the second channel layer may fill the remainder of the opening in the 3D NAND memory structure 100, as illustrated in FIG. 9.

In some embodiments, at least a portion of the first channel layer 208 and a portion of the second channel layer 210 formed within the opening 3D NAND memory structure 100 are coupled to the source region 212 layer and the first channel layer 208 and the second channel layer 210 are coupled to the drain region 214 layer.

In some embodiments, depositing the first channel layer 208 in the plurality of openings in the 3D NAND memory structure 100 may include depositing material on the side walls of the plurality of openings, as well as the bottom of the plurality of openings. In some embodiments, the method 600 may optionally include an etching process to remove a portion of the first channel layer 208 formed at the bottom of the plurality of openings in order to remove the portion of the first channel layer 208 from the bottom plurality of openings and allow a portion of the second channel 210 to contact the source region 212 (N+ source layer) after deposition. The etching of the portion of the bottom of the channel layer 208 can occur before the deposition of the second channel layer (e.g., 210) in activity 610, and may involve a sputter etching process, a wet etch, and/or a chemical dry etch.

Optionally, as shown in FIG. 10, at activity 612, a filler layer 302 may be deposited in the plurality of openings in a portion 1000 of the 3D NAND memory structure 100 on the second channel layer 210 which, in this configuration, does not completely fill the formed openings. For example, the filler layer material may be silicon dioxide (SiO₂), aluminum oxide (Al₂O₃), or silicon nitride (Si₃N₄). In some embodiments, the deposition of the filler layer may fill the remainder of the opening in the 3D NAND memory structure 100, as illustrated in FIG. 10.

The filler layer 302, such as an oxide layer, can be deposited using any suitable deposition processes and/or apparatus. For example, physical vapor deposition (PVD), atomic layer deposition (ALD) or chemical vapor deposition (CVD) may be used to deposit the first and second channel layers 208, 210, the ONO layer stack 206, and the filler layer 302. Alternatively or additionally, a stand-alone apparatus or a cluster tool can be used to perform an atomic layer deposition (ALD) process. Exemplary apparatus that can be configured for performing the above process include, for example, the OLYMPIA line of ALD apparatus, available from Applied Materials, Inc.

After performing the activities of method 600 on a portion (e.g., 200, 300, 700, 800, 900, 1000) of the 3D NAND memory structure 100, additional conventional processing steps will be performed on the portion of the 3D NAND memory structure 100 to complete the formation of a functioning 3D NAND device. For example, one processing step could include forming the drain region 214 and a plurality of bit lines 118 on top of the plurality of openings in the 3D NAND memory structure 100, as described herein with respect to FIG. 1. As a result of the deposition of the plurality of bit lines 118, the first channel 208 and second channel 210 may contact the drain region 214 (e.g., N+ drain layer).

In one embodiment, which can be combined with other embodiments described herein, the high mobility channel layer and/or the low or lower mobility channel layer used to form either of the layers within the multi-layer stack, such as the first and second channel layers 208, 210, will include indium (In), zinc (Zn), gallium (Ga), oxygen (O), tin (Sn), aluminum (Al), and/or hafnium (Hf). Examples of the high mobility channel layer include, but are not limited to, InGaZnO, InGaO, InZnO, InGaSnO, InZnSnO, InGaZnSnO, InSnO, HfInZnO, GaZnO, InO, IWO, AlSnZnO, ZnO, ZnSnO, AlZnO, AlZnSnO, HfZnO, SnO, and AlSnZnInO. Examples of the low or lower mobility channel layer include, but are not limited to, InGaZnO, GaO, InGaO, ZnSnO, InSnO, HfInZnO, AlSnZnO, ZnO, AlInZnSnO, and AlSnZnO.

In some embodiments, the material of the high mobility channel layer and the low mobility channel layer includes the same elements, but the stoichiometry of the material differs. For example, InGaZnO is a multi-component amorphous oxide semiconductor (AOS) system. InGaZnO typically shows mobility values of about 10 cm²N·s with 1:1:1 ratios of InO, GaO, and ZnO, but it is also possible to achieve mobility larger than 10 cm²N·s by increasing In and/or reducing Ga compositions from InGaZnO AOS systems. Therefore, mobility is adjustable by changing the compositions of components in AOS systems. ZnO or InO without Ga in AOS systems allow higher mobility (higher carrier concentration), but it can be difficult to obtain an amorphous phase. However, binary components such as ZnInO or ZnGaO can form amorphous phases due to changing composition of ZnO and InO. For high mobility (>20 cm2N·s) AOS, it is possible to increase carrier concentration by increasing the composition of In and/or decreasing the composition of Ga from multi-component AOS systems. Thus, in one embodiment, the low mobility channel layer includes InGaZnO, the high mobility layer includes InGaZnO, and the high mobility channel layer has a higher composition of In than the low mobility channel layer. In another embodiment, the low mobility layer includes InGaZnO, the high mobility channel layer includes InGaZnO, and the high mobility channel layer has a lower composition of Ga than the low mobility channel layer. In yet another embodiment, the low mobility layer includes InGaZnO, the high mobility channel layer includes InGaZnO, the high mobility channel layer has a higher composition of In than the low mobility channel layer, and the high mobility channel layer has a lower composition of Ga than the low mobility channel layer.

It is to be understood that the composition of In, Ga, Zn, and O can easily change electron transport properties (e.g., mobilities). For example, electron transport properties (e.g., mobilities) of In₂O₃Ga₂O₃ZnO (InGaZnO) thin films are determined by the composition of In₂O₃, Ga₂O₃, and ZnO by changing X, Y, and Z, where X is defined by [(ZnO)ₓ(Ga₂O₃)₁₋ₓ] mol %, Y is defined by [(Ga₂O₃)_{y}(In₂O₃)_{1-y}] mol %, and Z is defined by (In₂O₃)_{z}(ZnO)_{1-z}] mol %. In the InGaZnO system, it is generally understood that the In atoms contained therein act as In³⁺ ions that form electron pathways, which leads to high electron mobility. In addition, it is understood that Zn atoms contained therein act as Zn²⁺ ions that prefer tetrahedral coordination, which increases stability of an amorphous phase of InGaZnO. Finally, it is understood that Ga atoms contained therein act as Ga³⁺ ions that suppress carrier generation due to the high ionic field strength of the Ga³⁺ ions. Ga³⁺ ions form stronger chemical bonds with oxygen (O) atoms than the Zn and In atoms, due to O vacancy formation. Thus, increasing the Ga percentage leads to low mobility and/or carrier concentration, and thus a layer containing high Ga percentage leads to a low off current and large on/off current ratio. Additionally, in some embodiments, incorporation of tin (Sn) into the mixture can improve the stability and reliability due to the better bonding of oxygen.

If X=Y=Z=0.5, InGaZnO allows a mobility of about 9 cm²/Vs. Higher mobility can be controlled by decreasing Ga and increasing In. For example, if X=1, Y=0, Z=1, the composition is InO. If X=1, Y=0, Z=0, the composition is ZnO. However, InO and ZnO form a crystalline phase. If X=1, Y=0, 0<Z<1, the composition is InZnO. Therefore, InZnO has an amorphous phase and mobility larger than about 50 cm²V-s, which can be the material of the high mobility channel layer. InGaZnO has an amorphous phase and lower mobility less than about 20 cm²V·s, which can be the material of the low mobility channel layer.

The amorphous oxide semiconductor (AOS) systems can include InGaZnO, or other AOS including InZnO, ZnSnO, InGaO, InZnO, InGaSnO, InZnSnO, InGaZnSnO, InSnO, HfInZnO, GaZnO, InO, InWO, AlSnZnO, ZnO, ZnSnO, AlZnO, AlZnSnO, HfZnO, SnO, AlSnZnInO, and the like.

The methods and apparatus described herein can be used to form an improved planar or vertical or even 3D memory device structure. The multi-layer channel comprising two or more layers having differing materials described herein may allow for more area and multiple pathways for the current, and may transport larger total current through both the low mobility and the high mobility channel layers due to higher carrier density in the high mobility channel layer and carrier injection which acts as a positive feedback. Moreover, the use of a multi-layer channel may also allow for the utilization of channel materials other than polysilicon and 3D memory devices, which may decrease the variability of the stored state in 2D and 3D memory devices and those devices in general. The improved planar, vertical or 3D memory device structure may enable an increased memory density through the creation of more memory stacks (3D stacking) or strings (in 3D NAND architectures) and tighter distribution of the stored state, due to the minimization of the main scattering mechanisms which skews/broadens the bit distribution.

While the foregoing is directed to embodiments of the present disclosure, other and further embodiments of the disclosure may be devised without departing from the basic scope thereof, and the scope thereof is determined by the claims that follow.

We claim:

1. A three-dimensional memory device, comprising:
a plurality of alternating layers formed over a surface of a substrate, wherein the alternating layers comprises a word line layer and an inter-word line dielectric layer that are stacked in a first direction;
a gate coupled to each of the word line layers of the plurality of alternating layers;
a multi-layer channel having a first end coupled to a source region, a second end coupled to a drain region, and extending in the first direction between the source region and the drain region, wherein the multi-layer channel comprises:
a first conductive layer extending between the source region and the drain region; and
a second conductive layer extending between the source region and the drain region, wherein the first conductive layer is different from the second conductive layer; and
an ONO layer stack disposed between the gate and the multi-layer channel, wherein the ONO layer stack extends in the first direction between the source region and the drain region.

2. The device of claim 1, wherein the first conductive layer comprises indium zinc oxide (IZO), and the second conductive layer is disposed over the first conductive layer.

3. The device of claim 2, wherein the second conductive layer comprises indium gallium zinc oxide (IGZO).

4. The device of claim 1, wherein the second conductive layer comprises indium zinc oxide (IZO), and the first conductive layer is disposed over the second conductive layer.

5. The device of claim 4, wherein the first conductive layer comprises indium gallium zinc oxide (IGZO).

6. The device of claim 1, wherein the first conductive layer and the second conductive layer each comprises a metal oxide that comprises an element selected from the group consisting of: indium (In), zinc (Zn), gallium (Ga), tin (Sn), aluminum (Al), Tungsten (W) and hafnium (Hf).

7. The device of claim 6, wherein
the first conductive layer comprises InGaZnO, GaO, InGaO, ZnSnO, InSnO, HfInZnO, AlSnZnO, ZnO, AlInZnSnO, or AlSnZnO, and
the second conductive layer comprises InGaZnO, InGaO, InZnO, InGaSnO, InZnSnInGaZnSnO, InSnO, HfInZnO, GaZnO, InO, IWO, AlSnZnO, ZnO, ZnSnO, AlZnO, AlZnSnO, HfZnO, SnO, or AlSnZn.

8. A three-dimensional memory device, comprising:
a plurality of alternating layers formed over a surface of a substrate, wherein the alternating layers comprises a word line layer and an inter-word line dielectric layer that are stacked in a first direction;
a gate coupled to each of the word line layers of the plurality of alternating layers;
a multi-layer channel having a first end coupled to a source region, a second end coupled to a drain region, and extending in the first direction between the source region and the drain region, wherein the multi-layer channel comprises:
a first conductive layer extending between the source region and the drain region;
a second conductive layer extending between the source region and the drain region, wherein the first conductive layer is different from the second conductive layer; and
a filler layer extending between the source region and the drain region; and
an intermediate layer stack disposed between the gates and the multi-layer channel, wherein the intermediate layer stack extends in the first direction between the source region and the drain region.

9. The device of claim 8, wherein the intermediate layer stack comprises at least one layer that comprises silicon nitride (SiₓN_{y}) or hafnium oxide (HfOₓ).

10. The device of claim 8, wherein the first conductive layer comprises indium zinc oxide (IZO), and the second conductive layer is disposed over the first conductive layer.

11. The device of claim 9, wherein the second conductive layer comprises indium gallium zinc oxide (IGZO).

12. The device of claim 8, wherein the second conductive layer comprises indium zinc oxide (IZO), and the first conductive layer is disposed over the second conductive layer.

13. The device of claim 12, wherein the first conductive layer comprises indium gallium zinc oxide (IGZO).

14. The device of claim 8, wherein a material of the filler layer comprises silicon dioxide.

15. The device of claim 8, wherein a material of the filler layer comprises aluminum oxide.

16. The device of claim 8, wherein a material of the filler layer comprises silicon nitride.

17. The device of claim 8, wherein the first conductive layer and the second conductive layer each comprises a metal oxide that comprises an element selected from the group consisting of: indium (In), zinc (Zn), gallium (Ga), tin (Sn), aluminum (Al), and hafnium (Hf).

18. The device of claim 8, wherein
the first conductive layer comprises InGaZnO, GaO, InGaO, ZnSnO, InSnO, HfInZnO, AlSnZnO, ZnO, AlInZnSnO, or AlSnZnO, and
the second conductive layer comprises InGaZnO, InGaO, InZnO, InGaSnO, InZnSnInGaZnSnO, InSnO, HfInZnO, GaZnO, InO, AlSnZnO, ZnO, ZnSnO, AlZnO, AlZnSnO, HfZnO, SnO, or AlSnZn.

19. A method of forming a three-dimensional memory device, comprising:
forming a channel region within a plurality of openings formed through a plurality of alternating layers formed over a surface of a substrate, comprising:
forming an ONO layer stack over the surface of each of the plurality of openings;
forming a first conductive layer over a surface of the ONO layer stack; and
forming a second conductive layer over a surface of the first conductive layer, wherein the first conductive layer is different from the second conductive layer; and
forming a drain region layer over the plurality of alternating layers, wherein at least a portion of the first conductive layer and a portion of the second conductive layer formed within each of the plurality of openings are coupled to a portion of the drain region layer and at least a portion of the first conductive layer and a portion of the second conductive layer are coupled to a portion of a source region layer of the three-dimensional memory device.

20. The method of claim 19, wherein forming the channel region further comprises forming a filler layer over a surface of the formed second conductive layer, wherein the alternating layers comprise a word line layer and an inter-word line dielectric layer that are stacked in a first direction over the source region layer that is disposed over the surface of the substrate, and wherein the plurality of openings extend in the first direction from the source region layer and through the plurality of alternating layers.
